(19) United States
(12) Patent Application Publication
(10) Pub. No.: US 2026/0215254 A1
(43) Pub. Date: Jul. 23, 2026

(54) SEMICONDUCTOR CHIP AND SEMICONDUCTOR PACKAGE INCLUDING THE SAME

(71) Applicant: Samsung Electronics Co., Ltd., Suwon-si (KR)

(72) Inventors: Junghyun Roh, Suwon-si (KR); Hyesun Yoon, Suwon-si (KR); Jongho Lee, Suwon-si (KR); Hairyong Hong, Suwon-si (KR)

(21) Appl. No.: 19/354,619

(22) Filed: Oct. 9, 2025

(30) Foreign Application Priority Data
Jan. 20, 2025 (KR) 10-2025-0008022

(51) Int. Cl. H01L 23/525; H01L 23/00; H01L 23/31; H01L 23/498; H01L 25/065

(52) U.S. Cl. CPC H10W 20/493; H10W 20/491; H10W 72/884; H10W 74/111; H10W 90/00; H10W 90/701; H10W 90/732; H10W 90/734; H10W 90/752; H10W 90/754

(57) ABSTRACT

An example of a semiconductor chip includes a plurality of first pads, a first functional circuit, a plurality of first fuses and a first demultiplexer. The first functional circuit operates based on a first signal that is received from one of the plurality of first pads. The plurality of first fuses are disposed between the first functional circuit and the plurality of first pads. The first demultiplexer applies a first voltage to at least one of the plurality of first fuses based on a first control signal. One pad of the plurality of first pads is electrically connected to the first functional circuit through one fuse of the plurality of first fuses. Remaining pads of the plurality of first pads are electrically disconnected from the first functional circuit by remaining fuses of the plurality of first fuses.

### CROSS-REFERENCE TO RELATED APPLICATION

This application claims priority under 35 USC § 119 to Korean Patent Application No. 10-2025-0008022 filed on Jan. 20, 2025 in the Korean Intellectual Property Office (KIPO), the contents of which are herein incorporated by reference in their entirety.

### BACKGROUND

Electronic products may require high-capacity data processing while their volumes are gradually decreased. Electronic products include semiconductor chips, and a plurality of semiconductor chips may be stacked to form a single semiconductor package.

### SUMMARY

Example implementations relate generally to semiconductor integrated circuits, and more particularly to semiconductor chips and semiconductor packages including the semiconductor chips.

A semiconductor chip may include dummy pads. The dummy pads may be useful for electrically connecting stacked semiconductor chips to each other. For example, bonding wires may extend from signal pads of an upper semiconductor chip to a package substrate via dummy pads of a lower semiconductor chip. Since a middle portion of the relatively long bonding wires may be supported by the dummy pads, the shorting of the relatively long bonding wires due to a molding member may be suppressed.

At least one example implementation of the present disclosure provides a semiconductor chip capable of allowing a relatively free arrangement of bonding wires.

At least one example implementation of the present disclosure provides a semiconductor package including the semiconductor chip.

According to example implementations, a semiconductor chip includes a plurality of first pads, a first functional circuit, a plurality of first fuses and a first demultiplexer. The first functional circuit operates based on a first signal that is received from one of the plurality of first pads. The plurality of first fuses are disposed between the first functional circuit and the plurality of first pads. The first demultiplexer applies a high voltage to at least one of the plurality of first fuses based on a first control signal. One pad of the plurality of first pads is electrically connected to the first functional circuit through one fuse of the plurality of first fuses. Remaining pads of the plurality of first pads other than the one pad of the plurality of first pads are electrically disconnected from the first functional circuit by remaining fuses of the plurality of first fuses other than the one fuse of the plurality of first fuses.

According to example implementations, a semiconductor package includes a package substrate, a first semiconductor chip and a second semiconductor chip. The package substrate includes a plurality of substrate pads. The first semiconductor chip is disposed on the package substrate. The second semiconductor chip is disposed on the first semiconductor chip. The first semiconductor chip includes a plurality of first pads, a first functional circuit, a plurality of first fuses and a first demultiplexer. The first functional circuit operates based on a first signal that is received from a first substrate pad among the plurality of substrate pads through one of the plurality of first pads. The plurality of first fuses are disposed between the first functional circuit and the plurality of first pads. The first demultiplexer applies a high voltage to at least one of the plurality of first fuses based on a first control signal. One pad of the plurality of first pads is electrically connected to the first functional circuit through one fuse of the plurality of first fuses. Remaining pads of the plurality of first pads other than the one pad of the plurality of first pads are electrically disconnected from the first functional circuit by remaining fuses of the plurality of first fuses other than the one fuse of the plurality of first fuses.

According to example implementations, a semiconductor package includes a package substrate, a first semiconductor chip and a second semiconductor chip. The package substrate includes a plurality of substrate pads. The first semiconductor chip is disposed on the package substrate, and includes a plurality of first pads, a first functional circuit, a plurality of first fuses and a first demultiplexer. The plurality of first fuses are disposed between the first functional circuit and the plurality of first pads. The first demultiplexer applies a high voltage to at least one of the plurality of first fuses based on a first control signal. The second semiconductor chip is disposed on the first semiconductor chip, and includes a plurality of second pads, a second functional circuit, a plurality of second fuses and a second demultiplexer. The plurality of second fuses are disposed between the second functional circuit and the plurality of second pads. The second demultiplexer applies the high voltage to at least one of the plurality of second fuses based on a second control signal. The first functional circuit operates based on a first signal that is received from a first substrate pad among the plurality of substrate pads through a first one of the plurality of first pads, and based on a second signal that is received from a second substrate pad among the plurality of substrate pads through a second one of the plurality of first pads. The first one of the plurality of first pads that receives the first signal and the second one of the plurality of first pads that receives the second signal are electrically connected to the first functional circuit through two of the plurality of first fuses. The second functional circuit operates based on the first signal that is received from the first substrate pad through a first one of the plurality of second pads, and based on a third signal that is received from a third substrate pad among the plurality of substrate pads through a second one of the plurality of second pads. The first one of the plurality of second pads that receives the first signal and the second one of the plurality of second pads that receives the third signal are electrically connected to the second functional circuit through two of the plurality of second fuses. A first position in the first semiconductor chip and a second position in the second semiconductor chip are in a same position. The first position is a position on which the first one of the plurality of first pads that receives the first signal is disposed. The second position is a position on which the first one of the plurality of second pads that receives the first signal is disposed. A third position in the first semiconductor chip and a fourth position in the second semiconductor chip are in different positions. The third position is a position on which the second one of the plurality of first pads that receives the second signal is disposed. The fourth position is a position on which the second one of the plurality of second pads that receives the third signal is disposed.

In the semiconductor chip and the semiconductor package according to example implementations, one pad that is used to receive the specific signal may be selected and changed using the plurality of fuses and the demultiplexer. In other words, the pad coordinate variable scheme in which the role and function of pads are changeable may be implemented. Accordingly, when the semiconductor package is manufactured using the semiconductor chips, a relatively free arrangement of bonding wires may be implemented, defects of bonding wires such as open and short may be efficiently controlled, and the usage amount of bonding wire may be reduced.

### BRIEF DESCRIPTION OF THE DRAWINGS

Illustrative, non-limiting example implementations will be more clearly understood from the following detailed description taken in conjunction with the accompanying drawings.

FIG. 1 is a block diagram illustrating a semiconductor chip according to example implementations.

FIG. 2 is a block diagram illustrating an example of a semiconductor chip of FIG. 1 according to example implementations.

FIGS. 3A, 3B, 3C, 3D, 3E and 3F are diagrams for describing an operation of a semiconductor memory device of FIG. 2 according to example implementations.

FIG. 4 is a block diagram illustrating an example of a semiconductor chip of FIG. 1 according to example implementations.

FIGS. 5A and 5B are diagrams for describing an operation of a semiconductor memory device of FIG. 4 according to example implementations.

FIG. 6 is a block diagram illustrating an example of a semiconductor chip of FIG. 1 according to example implementations.

FIGS. 7A, 7B and 7C are diagrams for describing an operation of a semiconductor memory device of FIG. 6 according to example implementations.

FIGS. 8 and 9 are block diagrams illustrating a semiconductor chip according to example implementations.

FIGS. 10A and 10B are block diagrams illustrating examples of a semiconductor chip according to example implementations.

FIG. 11 is a cross-sectional view of a semiconductor package according to example implementations.

FIGS. 12 and 13 are plan views of examples of a semiconductor package of FIG. 11 according to example implementations.

FIG. 14 is a block diagram illustrating a memory system according to example implementations.

### DETAILED DESCRIPTION

Various example implementations will be described more fully with reference to the accompanying drawings, in which implementations are shown. The present disclosure may, however, be embodied in many different forms and should not be construed as limited to the implementations set forth herein. Like reference numerals refer to like elements throughout this application.

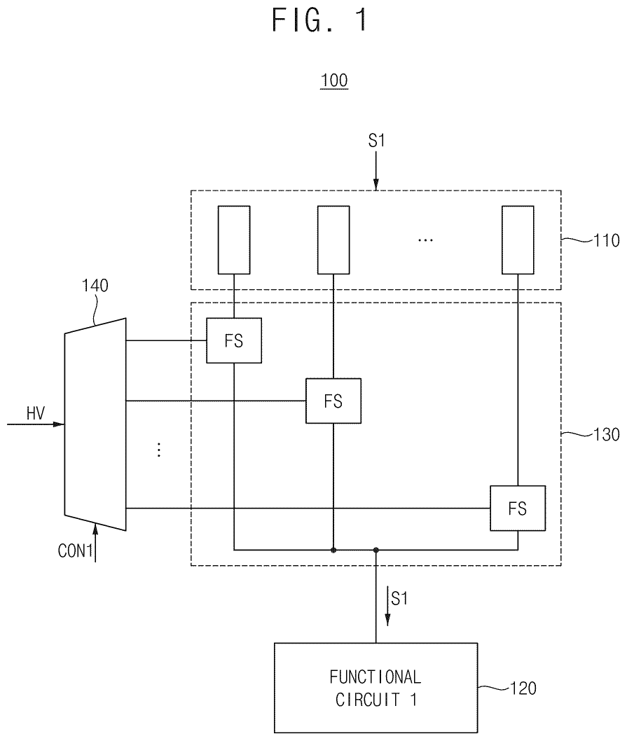

FIG. 1 is a block diagram illustrating a semiconductor chip according to example implementations.

Referring to FIG. 1, a semiconductor chip 100 includes a plurality of first pads 110, a first functional circuit 120, a plurality of first fuses (FSs) 130 and a first demultiplexer 140.

The plurality of first pads 110 receive a first signal S1 that is required to operate the semiconductor chip 100. For example, the plurality of first pads 110 may include a first signal pad to an N-th signal pad, where N is a positive integer greater than or equal to two. For example, a pad may be or may include a contact pad or a contact pin, but example implementations are not limited thereto.

The first functional circuit 120 operates based on the first signal S1 that is received from one of the plurality of first pads 110. The first functional circuit 120 may perform a unique function for operating the semiconductor chip 100.

In some example implementations, when the semiconductor chip 100 is a memory chip, the first functional circuit 120 may be a control logic and/or a control circuit that controls an operation of the memory chip, or a memory cell array that stores data within the memory chip. However, example implementations are not limited thereto.

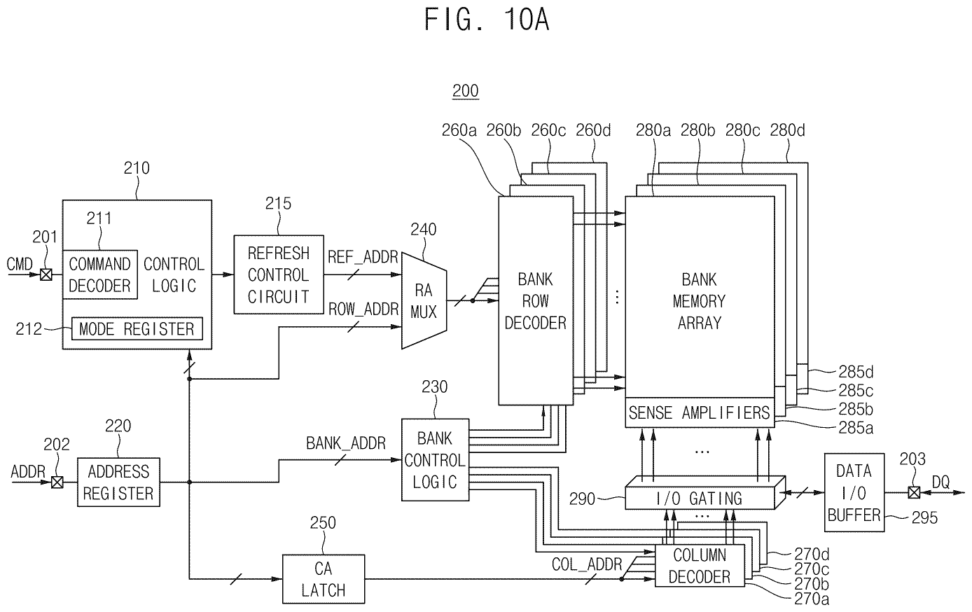

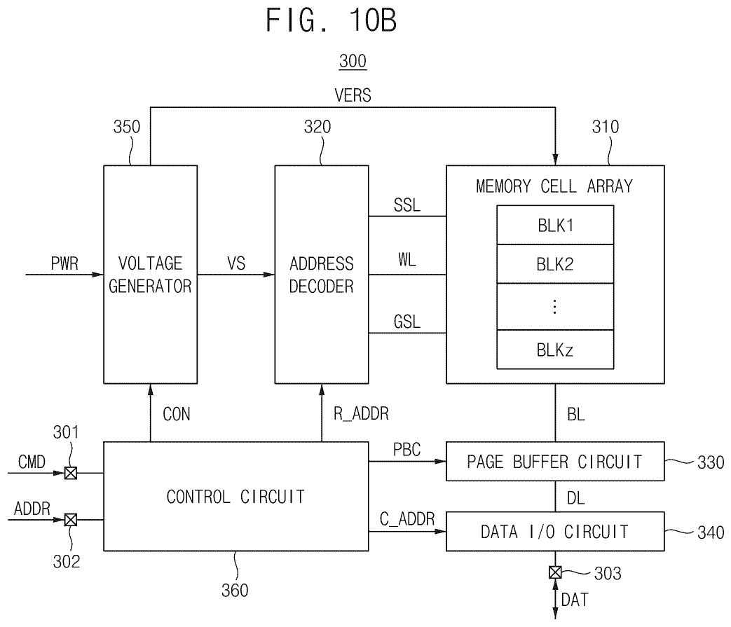

Detailed examples of the semiconductor chip 100 and the first functional circuit 120 will be described with reference to FIGS. 10A and 10B.

The plurality of first fuses 130 are disposed or arranged between the first functional circuit 120 and the plurality of first pads 110. For example, each of the plurality of first fuses 130 may be disposed between the first functional circuit 120 and a respective one of the plurality of first pads 110. In other words, one first fuse may be disposed to correspond to one first pad, and thus the number of the plurality of first fuses 130 may be equal to the number of the plurality of first pads 110. For example, the semiconductor chip 100 may include N first fuses.

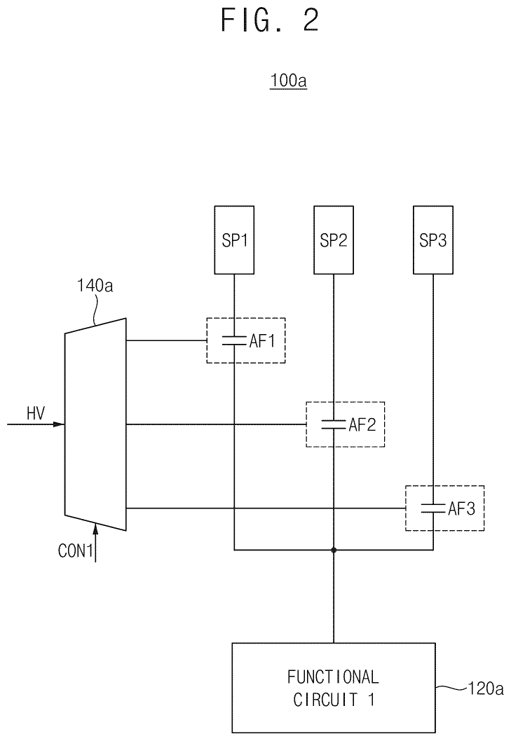

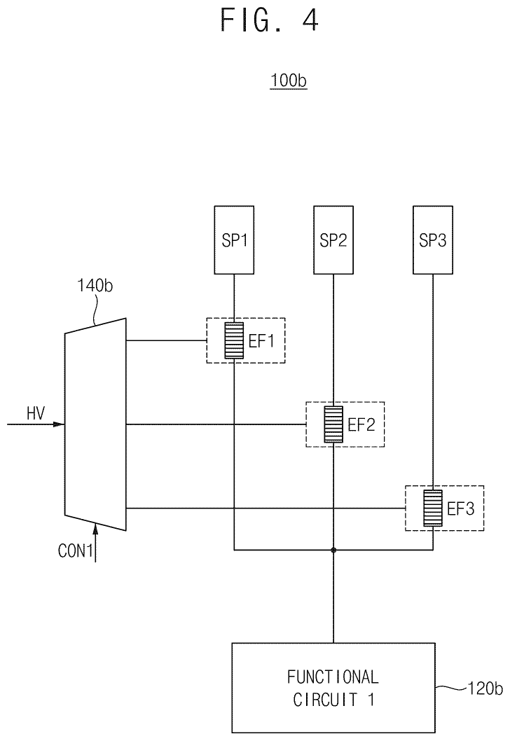

In some example implementations, the plurality of first fuses 130 may include fuses of the same type. For example, as will be described with reference to FIG. 2, the plurality of first fuses 130 may include a plurality of anti-fuses. For example, as will be described with reference to FIG. 4, the plurality of first fuses 130 may include a plurality of electrical fuses (E-fuses).

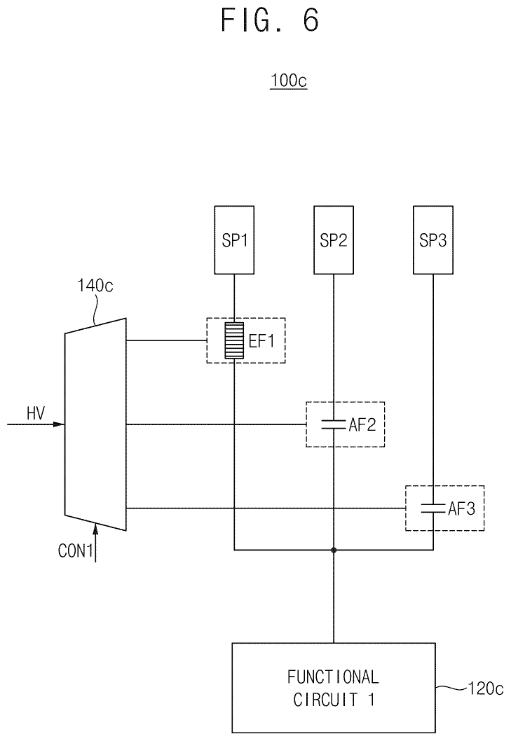

In some example implementations, the plurality of first fuses 130 may include fuses of different types. For example, as will be described with reference to FIG. 6, the plurality of first fuses 130 may include both electrical fuses and anti-fuses.

The first demultiplexer 140 applies a high voltage HV (e.g., a first voltage) to at least one of the plurality of first fuses 130 based on a first control signal CON1. The at least one of the plurality of first fuses 130 to which the high voltage HV is applied may be programmed.

In some example implementations, the first control signal CON1 for selecting a fuse to be programmed among the plurality of first fuses 130 may be provided from the outside of the semiconductor chip 100. For example, the first control signal CON1 may be provided from a test equipment for testing the semiconductor chip 100, but example implementations are not limited thereto.

For example, one pad of the plurality of first pads 110 may be electrically connected to the first functional circuit 120 through one fuse of the plurality of first fuses 130, and remaining pads of the plurality of first pads 110 other than the one pad of the plurality of first pads 110 may be electrically disconnected or isolated from the first functional circuit 120 by remaining fuses of the plurality of first fuses 130 other than the one fuse of the plurality of first fuses 130. For example, only the one pad of the plurality of first pads 110 that is electrically connected to the first functional circuit 120 may be used as a pad for receiving the first signal S1, and the remaining pads of the plurality of first pads 110 other than the one pad of the plurality of first pads 110 may be provided as dummy pads. In other words, the plurality of first pads 110 that are used to receive the first signal S1 may be set as one pad group, and one pad may be selected and used from the one pad group.

In some example implementations, based on the type of each fuse, each of the plurality of first fuses 130 may operate as one of an open circuit and a short circuit before being programmed (e.g., at an initial operation time), and may operate as the other of the open circuit and the short circuit after being programmed. For example, when a specific fuse among the plurality of first fuses 130 is selected and programmed using the first control signal CON1, the one pad of the plurality of first pads 110 may be electrically connected to the first functional circuit 120, and the remaining pads of the plurality of first pads 110 may be electrically disconnected from the first functional circuit 120.

In some example implementations, the one pad of the plurality of first pads 110 that is electrically connected to the first functional circuit 120, e.g., the one pad of the plurality of first pads 110 that is used to receive the first signal S1, may be changeable. For example, when the program of the plurality of first fuses 130 is controlled using the first control signal CON1, a specific pad to be electrically connected to the first functional circuit 120 may be selected and changed. In other words, the one pad that is selected and used from the one pad group may be changeable. For example, the semiconductor chip may initially select a first signal pad for receiving the signals, and later deselect the first signal pad and select a second signal pad for receiving the signals.

In the semiconductor chip 100 according to example implementations, one pad among the plurality of pads 110 that is used to receive the signal S1 (e.g., that is electrically connected to the functional circuit 120) may be selected and changed using the plurality of fuses 130 and the demultiplexer 140. In other words, a pad coordinate variable scheme in which the role and function of pads are changeable may be implemented. Accordingly, when a semiconductor package is manufactured using the semiconductor chip 100, a relatively free arrangement of bonding wires may be implemented.

FIG. 2 is a block diagram illustrating an example of a semiconductor chip of FIG. 1.

Referring to FIG. 2, a semiconductor chip 100a may include first, second and third signal pads SP1, SP2 and SP3, a first functional circuit 120a, first, second and third anti-fuses AF1, AF2 and AF3, and a first demultiplexer 140a.

FIG. 2 illustrates an example where the semiconductor chip 100 of FIG. 1 includes three pads and three fuses, (e.g., N=3), and illustrates an example where the plurality of first fuses 130 in FIG. 1 include fuses of the same type (e.g., only include anti-fuses). The first functional circuit 120a and the first demultiplexer 140a may be substantially the same as the first functional circuit 120 and the first demultiplexer 140 in FIG. 1, respectively. The descriptions repeated with or overlapping with descriptions of FIG. 1 will be omitted in the interest of brevity.

The first anti-fuse AF1 may be disposed between the first signal pad SP1 and the first functional circuit 120a, and may control an electrical connection between the first signal pad SP1 and the first functional circuit 120a. The second anti-fuse AF2 may be disposed between the second signal pad SP2 and the first functional circuit 120a, and may control an electrical connection between the second signal pad SP2 and the first functional circuit 120a. The third anti-fuse AF3 may be disposed between the third signal pad SP3 and the first functional circuit 120a, and may control an electrical connection between the third signal pad SP3 and the first functional circuit 120a.

A laser fuse, as one of the widely used fuses, is programmed by cutting the fuse formed with a metal line using laser beam. The laser fuse has an advantage of being simply embodied since an additional circuit to control cutting of the fuse is unnecessary. The laser fuse, however, has disadvantages of limitation to the integration density regardless of the development of the semiconductor chip manufacturing process technology, such as a metal oxide semiconductor (MOS) process, since a predetermined interval between the fuses has to be secured to prevent damages due to laser fusing. Furthermore the laser fuse may not be reprogrammed after the semiconductor chip including the fuse circuit is packaged. To overcome these disadvantages, an electrical fuse and an anti-fuse programmed by using an electrical signal have been proposed. Those fuses have advantages that they may be reprogrammed even after the semiconductor chip is packaged since they are activated or deactivated by the electrical signal. In addition, the size of the fuse circuit may be reduced as the scale of the manufacturing process is reduced.

Before the anti-fuse is programmed, the anti-fuse may have a sufficiently large resistance and may operate as an open circuit, and thus the transmission of signal through the anti-fuse may be blocked. After the anti-fuse is programmed and is electrically shorted, the anti-fuse may have a sufficiently small resistance and may operate as a short circuit, and thus the transmission of signal through the anti-fuse may be possible. In other words, the anti-fuse may have characteristics opposite to those of a typical fuse, which operates as a short circuit before being programmed and as an open circuit after being programmed.

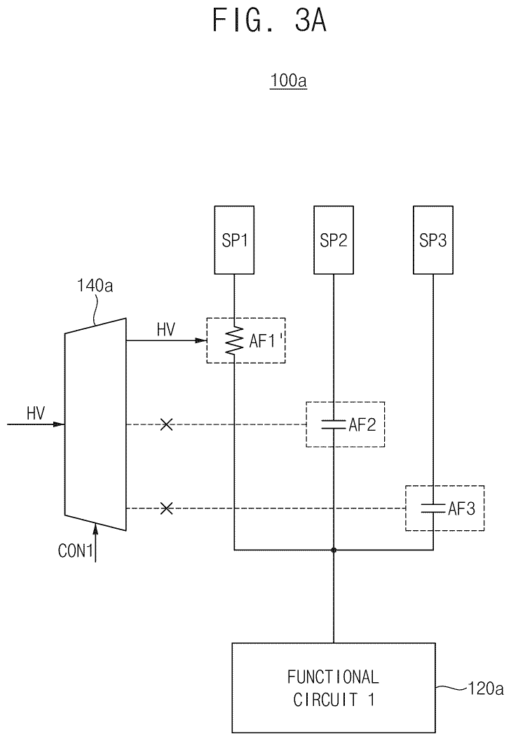

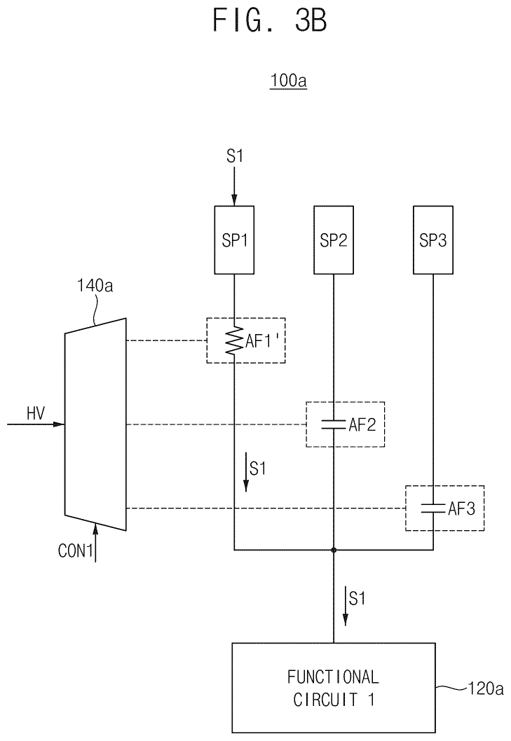

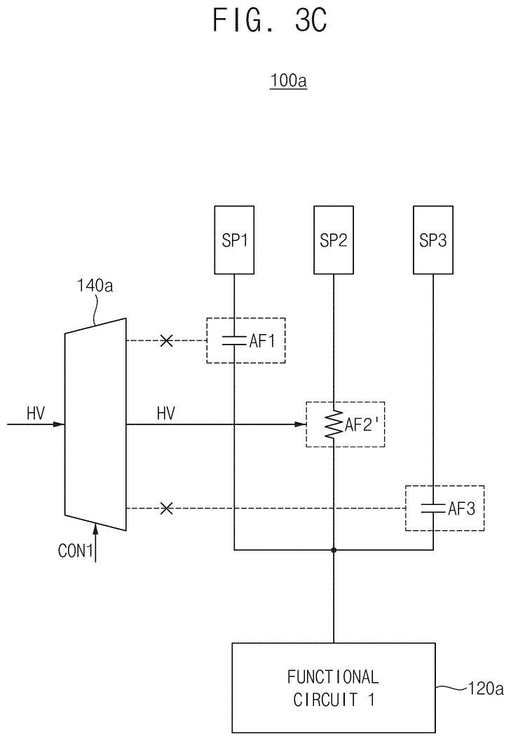

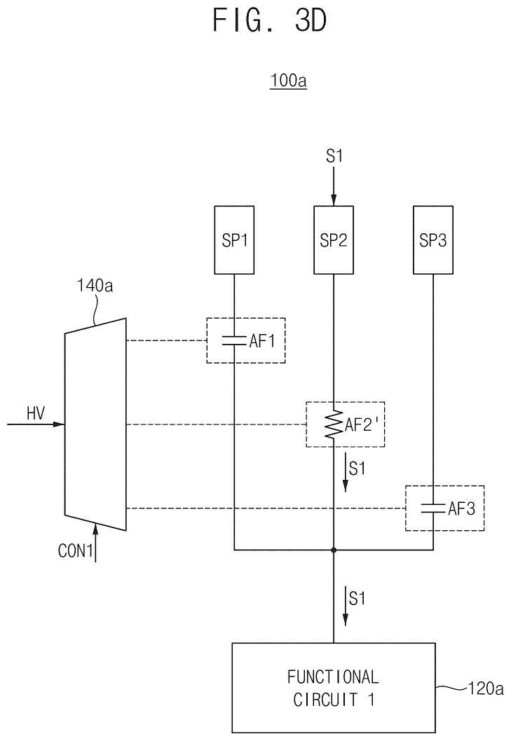

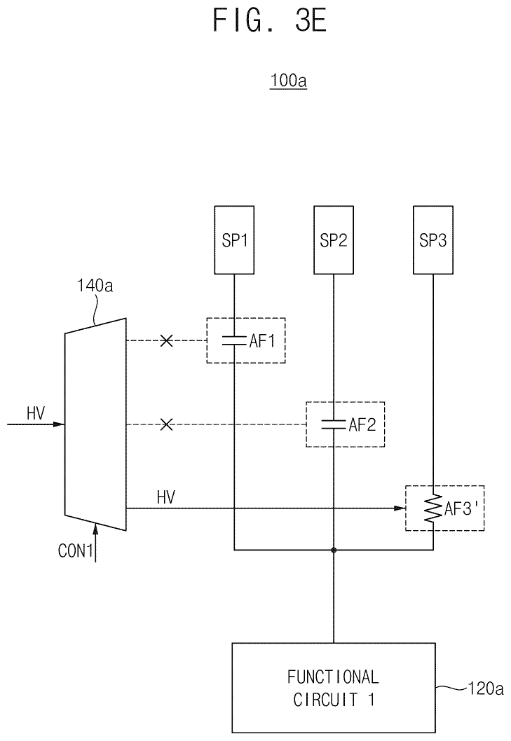

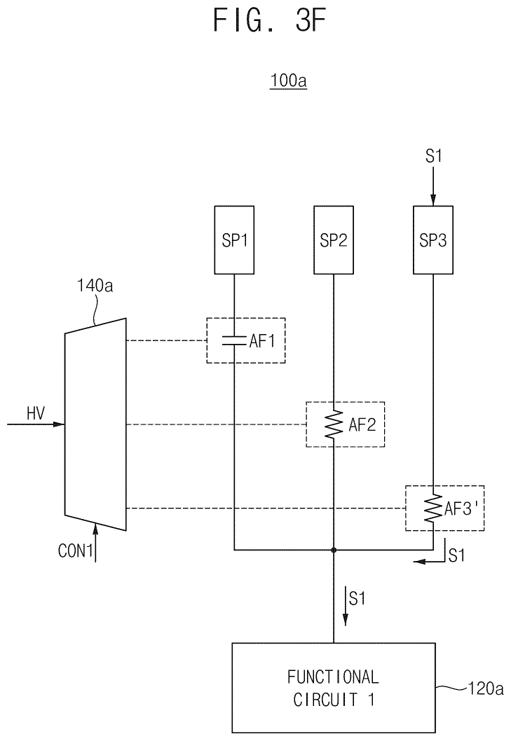

FIGS. 3A, 3B, 3C, 3D, 3E and 3F are diagrams for describing an operation of a semiconductor memory device of FIG. 2.

Referring to FIGS. 3A, 3B, 3C, 3D, 3E and 3F, an example where one of the first, second and third signal pads SP1, SP2 and SP3 in the semiconductor chip 100a is electrically connected to the first functional circuit 120a and is used as a signal pad for receiving the first signal S1 is illustrated, and an example where one of the first, second and third signal pads SP1, SP2 and SP3, which is electrically connected to the first functional circuit 120a (e.g., used to receive the first signal S1), is changeable is illustrated.

In some example implementations, as illustrated in FIGS. 3A and 3B, the first signal pad SP1 may be selected and may be electrically connected to the first functional circuit 120a, and the first signal S1 may be received through the first signal pad SP1 and may be provided to the first functional circuit 120a.

For example, as illustrated in FIG. 3A, the first demultiplexer 140a may apply the high voltage HV to the first anti-fuse AF1 and may block the application of the high voltage HV to the second and third anti-fuses AF2 and AF3, based on the first control signal CON1. Therefore, the first anti-fuse AF1 may be programmed, and the programmed first anti-fuse AF1′ may operate as a short circuit having a relatively low resistance. The second and third anti-fuses AF2 and AF3 may not be programmed and may operate as open circuits having relatively high resistances.

Thereafter, as illustrated in FIG. 3B, the first signal pad SP1 may receive the first signal S1, the received first signal S1 may be provided to the first functional circuit 120a through the programmed first anti-fuse AF1′, and the first functional circuit 120a may operate based on the first signal S1. Since the second and third anti-fuses AF2 and AF3 are not programmed, the second and third signal pads SP2 and SP3 may not provide the first signal S1 to the first functional circuit 120a even if the second and third signal pads SP2 and SP3 receive the first signal S1, and thus the second and third signal pads SP2 and SP3 may function as dummy pads.

In some example implementations, as illustrated in FIGS. 3C and 3D, the second signal pad SP2 may be selected and may be electrically connected to the first functional circuit 120a, and the first signal S1 may be received through the second signal pad SP2 and may be provided to the first functional circuit 120a. The descriptions repeated with or overlapping with descriptions of FIGS. 3A and 3B will be omitted in the interest of brevity.

For example, as illustrated in FIG. 3C, the first demultiplexer 140a may apply the high voltage HV to the second anti-fuse AF2 based on the first control signal CON1, and thus the second anti-fuse AF2 may be programmed. The first demultiplexer 140a may block the application of the high voltage HV to the first and third anti-fuses AF1 and AF3, and thus the first and third anti-fuses AF1 and AF3 may not be programmed.

Thereafter, as illustrated in FIG. 3D, the second signal pad SP2 may receive the first signal S1, the received first signal S1 may be provided to the first functional circuit 120a through the programmed second anti-fuse AF2′, and the first functional circuit 120a may operate based on the first signal S1.

In some example implementations, as illustrated in FIGS. 3E and 3F, the third signal pad SP3 may be selected and may be electrically connected to the first functional circuit 120a, and the first signal S1 may be received through the third signal pad SP3 and may be provided to the first functional circuit 120a. The descriptions repeated with or overlapping with descriptions of FIGS. 3A and 3B will be omitted in the interest of brevity.

For example, as illustrated in FIG. 3E, the first demultiplexer 140a may apply the high voltage HV to the third anti-fuse AF3 based on the first control signal CON1, and thus the third anti-fuse AF3 may be programmed. The first demultiplexer 140a may block the application of the high voltage HV to the first and second anti-fuses AF1 and AF2, and thus the first and second anti-fuses AF1 and AF2 may not be programmed.

Thereafter, as illustrated in FIG. 3F, the third signal pad SP3 may receive the first signal S1, the received first signal S1 may be provided to the first functional circuit 120a through the programmed third anti-fuse AF3′, and the first functional circuit 120a may operate based on the first signal S1.

In some example implementations, the operations of selecting and programming one of the first to third anti-fuses AF1, AF2 and AF3 described with reference to FIGS. 3A, 3C and 3E may be performed after the semiconductor chip 100a is manufactured and before the semiconductor chip 100a is tested. For example, a test operation for the semiconductor chip 100a may include a test performed in an electrical die sorting (EDS) process and/or a test performed after a packaging process, but example implementations are not limited thereto.

After a plurality of semiconductor chips (or dies) are fabricated by performing an oxidation process, a photolithography process, an etching process, a deposition and/or ion implantation process, a metal wiring process, etc. on a semiconductor wafer, the EDS process may be performed to check whether each semiconductor chip has reached a target quality level. For example, electrical tests, wafer burn-in tests, hot/cold tests, repair/final tests, etc. may be performed, and finally, defective chips may be identified by inking. Each semiconductor chip may be provided by cutting the semiconductor wafer after the EDS process.

In addition, to protect the semiconductor chips that is cut and/or separated from the semiconductor wafer from various external environments, a semiconductor package may be fabricated by performing the packaging process on the semiconductor chips. For example, the semiconductor chips may be mounted on and electrically connected to a package substrate (e.g., printed circuit board (PCB), etc.), a sealing member covering the package substrate and the semiconductor chips may be formed, connection structures (e.g., bumps, solder balls, etc.) for electrical connection between a lower surface of the package substrate and an external device may be formed, and thus the semiconductor package may be obtained.

FIG. 4 is a block diagram illustrating an example of a semiconductor chip of FIG. 1.

Referring to FIG. 4, a semiconductor chip 100b may include first, second and third signal pads SP1, SP2 and SP3, a first functional circuit 120b, first, second and third electrical fuses EF1, EF2 and EF3, and a first demultiplexer 140b.

FIG. 4 illustrates an example where the semiconductor chip 100 of FIG. 1 includes three pads and three fuses, (e.g., N=3), and illustrates an example where the plurality of first fuses 130 in FIG. 1 include fuses of the same type (e.g., only include electrical fuses). The first functional circuit 120b and the first demultiplexer 140b may be substantially the same as the first functional circuit 120 and the first demultiplexer 140 in FIG. 1, respectively. The descriptions repeated with or overlapping with descriptions of FIG. 1 will be omitted in the interest of brevity.

The first electrical fuse EF1 may be disposed between the first signal pad SP1 and the first functional circuit 120b, and may control an electrical connection between the first signal pad SP1 and the first functional circuit 120b. The second electrical fuse EF2 may be disposed between the second signal pad SP2 and the first functional circuit 120b, and may control an electrical connection between the second signal pad SP2 and the first functional circuit 120b. The third electrical fuse EF3 may be disposed between the third signal pad SP3 and the first functional circuit 120b, and may control an electrical connection between the third signal pad SP3 and the first functional circuit 120b.

Before the electrical fuse is programmed, the electrical fuse may have a sufficiently small resistance and may operate as a short circuit, and thus the transmission of signal through the electrical fuse may be possible. After the electrical fuse is programmed and is cut, the electrical fuse may have a sufficiently large resistance and may operate as an open circuit, and thus the transmission of signal through the electrical fuse may be blocked.

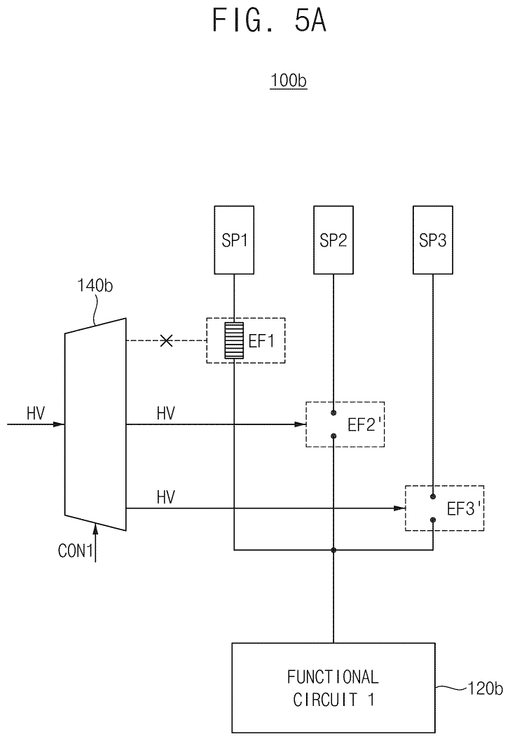

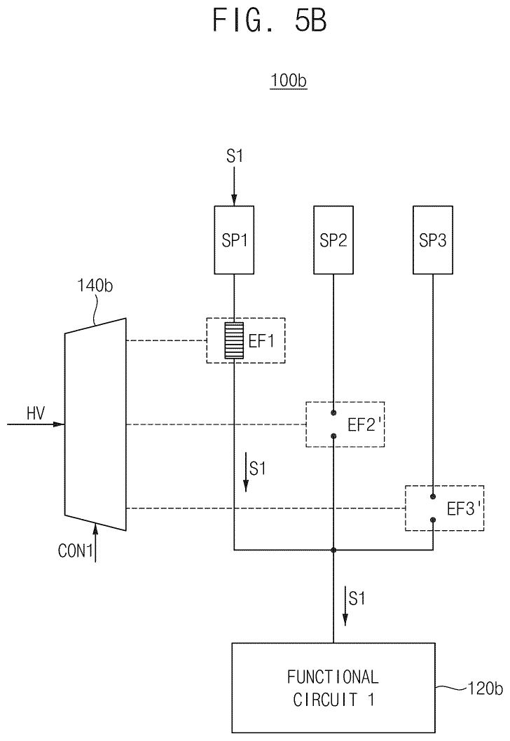

FIGS. 5A and 5B are diagrams for describing an operation of a semiconductor memory device of FIG. 4.

Referring to FIGS. 5A and 5B, an example where the first signal pad SP1 in the semiconductor chip 100b is electrically connected to a first functional circuit 120b and is used as a signal pad for receiving the first signal S1 is illustrated.

For example, as illustrated in FIG. 5A, the first signal pad SP1 may be selected and may be electrically connected to the first functional circuit 120b. For example, the first demultiplexer 140b may apply the high voltage HV to the second and third electrical fuses EF2 and EF3 and may block the application of the high voltage HV to the first electrical fuse EF1, based on the first control signal CON1. Therefore, the second and third electrical fuses EF2 and EF3 may be programmed, and the programmed second and third electrical fuses EF2′ and EF3′ may operate as open circuits having relatively high resistances. The first electrical fuse EF1 may not be programmed and may operate as a short circuit having a relatively low resistance.

Thereafter, as illustrated in FIG. 5B, the first signal S1 may be received through the first signal pad SP1 and may be provided to the first functional circuit 120b. For example, the first signal pad SP1 may receive the first signal S1, the received first signal S1 may be provided to the first functional circuit 120b through the first electrical fuse EF1 that is not programmed, and the first functional circuit 120b may operate based on the first signal S1. Since the second and third electrical fuses EF2 and EF3 are programmed, the second and third signal pads SP2 and SP3 may not provide the first signal S1 to the first functional circuit 120b even if the second and third signal pads SP2 and SP3 receive the first signal S1, and thus the second and third signal pads SP2 and SP3 may function as dummy pads.

Although not illustrated in detail, as with those described with reference to FIGS. 3A, 3B, 3C, 3D, 3E and 3F, one of the first, second and third signal pads SP1, SP2 and SP3, which is electrically connected to the first functional circuit 120b (e.g., used to receive the first signal S1), may be changeable. For example, as with that described with reference to FIGS. 3C and 3D, the second signal pad SP2 may be selected and may be electrically connected to the first functional circuit 120b, and the first and third electrical fuses EF1 and EF3 may be programmed and the second electrical fuse EF2 may not be programmed. For example, as with that described with reference to FIGS. 3E and 3F, the third signal pad SP3 may be selected and may be electrically connected to the first functional circuit 120b, and the first and second electrical fuses EF1 and EF2 may be programmed and the third electrical fuse EF3 may not be programmed.

FIG. 6 is a block diagram illustrating an example of a semiconductor chip of FIG. 1.

Referring to FIG. 6, a semiconductor chip 100c may include first, second and third signal pads SP1, SP2 and SP3, a first functional circuit 120c, an electrical fuse EF1, anti-fuses AF2 and AF3, and a first demultiplexer 140c.

FIG. 6 illustrates an example where the semiconductor chip 100 of FIG. 1 includes three pads and three fuses, (e.g., N=3), and illustrates an example where the plurality of first fuses 130 in FIG. 1 include fuses of the different type (e.g., include both electrical fuses and anti-fuses). The first functional circuit 120c and the first demultiplexer 140c may be substantially the same as the first functional circuit 120 and the first demultiplexer 140 in FIG. 1, respectively. The descriptions repeated with or overlapping with descriptions of FIGS. 1, 2 and 4 will be omitted in the interest of brevity.

The electrical fuse EF1 may be disposed between the first signal pad SP1 and the first functional circuit 120c, and may be substantially the same as the first electrical fuse EF1 in FIG. 4. The anti-fuse AF2 may be disposed between the second signal pad SP2 and the first functional circuit 120c, and may be substantially the same as the second anti-fuse AF2 in FIG. 2. The anti-fuse AF3 may be disposed between the third signal pad SP3 and the first functional circuit 120c, and may be substantially the same as the third anti-fuse AF3 in FIG. 2.

However, example implementations are not limited thereto. In some example implementations, a fuse connected to the second signal pad SP2 or the third signal pad SP3 may be an electrical fuse. In some example implementations, among three fuses connected to the three signal pads SP1, SP2 and SP3, two fuses may be electrical fuses and one fuse may be an anti-fuse.

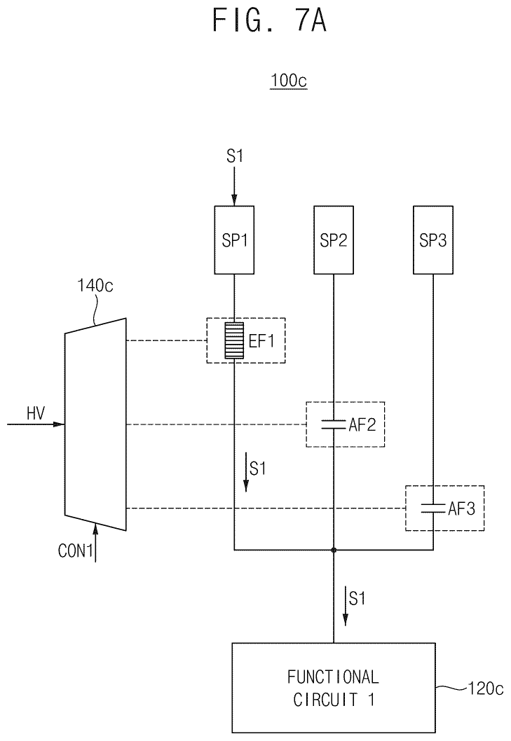

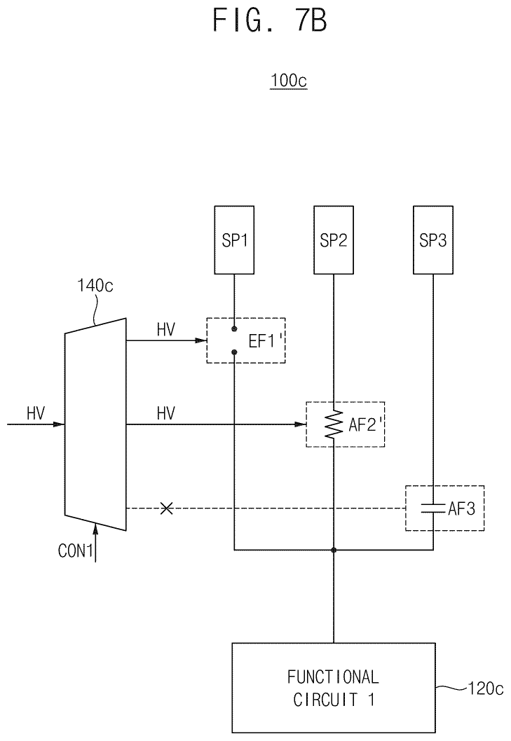

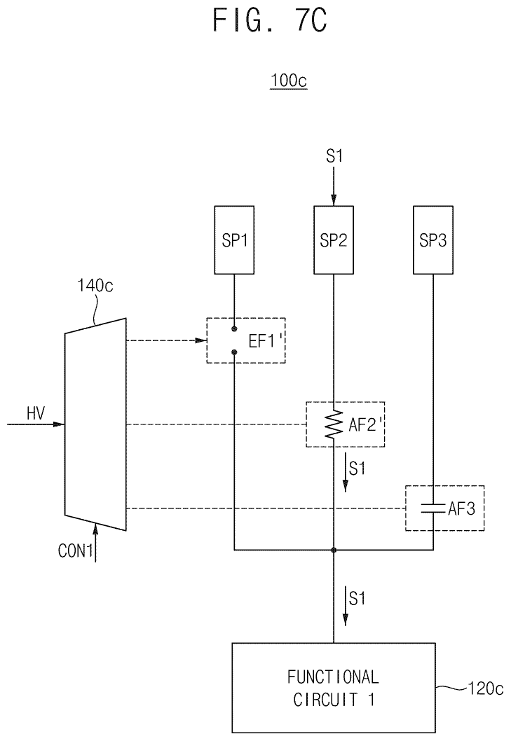

FIGS. 7A, 7B and 7C are diagrams for describing an operation of a semiconductor memory device of FIG. 6.

Referring to FIGS. 7A, 7B and 7C, an example before a first time point where the first signal pad SP1 in the semiconductor chip 100c is electrically connected to the first functional circuit 120c and is used as a signal pad for receiving the first signal S1 is illustrated, and an example after the first time point where the second signal pad SP2 in the semiconductor chip 100c is electrically connected to the first functional circuit 120c and is used as a signal pad for receiving the first signal S1 is illustrated. The descriptions repeated with or overlapping with descriptions of FIGS. 3A, 3B, 3C, 3D, 5A and 5B will be omitted in the interest of brevity.

For example, as illustrated in FIG. 7A, before the first time point (e.g., at the initial operation time), the first signal pad SP1 that is connected to the electrical fuse EF1 may be electrically connected to the first functional circuit 120c, and the first signal S1 may be received through the first signal pad SP1 and may be provided to the first functional circuit 120c.

Thereafter, as illustrated in FIG. 7B, at the first time point, the second signal pad SP2 may be selected and may be electrically connected to the first functional circuit 120c, and the electrical connection between the first signal pad SP1 and the first functional circuit 120c may be blocked. For example, the first demultiplexer 140c may apply the high voltage HV to the electrical fuse EF1 and the anti-fuse AF2 and may block the application of the high voltage HV to the anti-fuse AF3, based on the first control signal CON1. Therefore, the electrical fuse EF1 and the anti-fuse AF2 may be programmed, and the programmed electrical fuse EF1′ may operate as an open circuit having a relatively high resistance, and the programmed anti-fuse AF2′ may operate as a short circuit having a relatively low resistance. The anti-fuse AF3 may not be programmed and may operate as an open circuit having a relatively high resistance.

In some example implementations, a voltage level of the high voltage HV for programming the electrical fuse EF1 and a voltage level of the high voltage HV for programming the anti-fuse AF2 may be substantially the same as or different from each other. For example, the electrical fuse EF1 and the anti-fuse AF2 may be programmed substantially simultaneously or concurrently when programmed based on the high voltage HV having the same voltage level. For example, the electrical fuse EF1 and the anti-fuse AF2 may be programmed at different time points when programmed based on the high voltage HV with different voltage levels.

Thereafter, as illustrated in FIG. 7C, after the first time point, the first signal S1 may be received through the second signal pad SP2 and may be provided to the first functional circuit 120c. For example, the first signal pad SP1 may receive the first signal (S1), the received first signal S1 may be provided to the first functional circuit 120c through the programmed anti-fuse AF2′, and the first functional circuit 120c may operate based on the first signal S1.

In some example implementations, FIG. 7A may represent an operation in a test performed during the EDS process, FIG. 7B may represent an operation before a test performed during the packaging process, and FIG. 7C may represent an operation in the test performed during the packaging process. In other words, the semiconductor chip 100c may operate using the first signal pad SP1 in the test performed during the EDS process, and may operate using the second signal pad SP2 in the test performed during the packaging process. However, example implementations are not limited thereto.

Although not illustrated in detail, as with those described with reference to FIGS. 3A, 3B, 3E and 3F, one of the second and third signal pads SP2 and SP3, which is electrically connected to the first functional circuit 120c, (e.g., used to receive the first signal S1), may be changeable. For example, as with that described with reference to FIGS. 3E and 3F, the third signal pad SP3 may be selected and may be electrically connected to the first functional circuit 120c.

Although example implementations are described based on the examples where the number of signal pads and the number of fuses are three and the fuses include anti-fuses and/or electrical fuses, example implementations are not limited thereto, and the number of signal pads and/or the types and number of fuses may be variously determined according to example implementations.

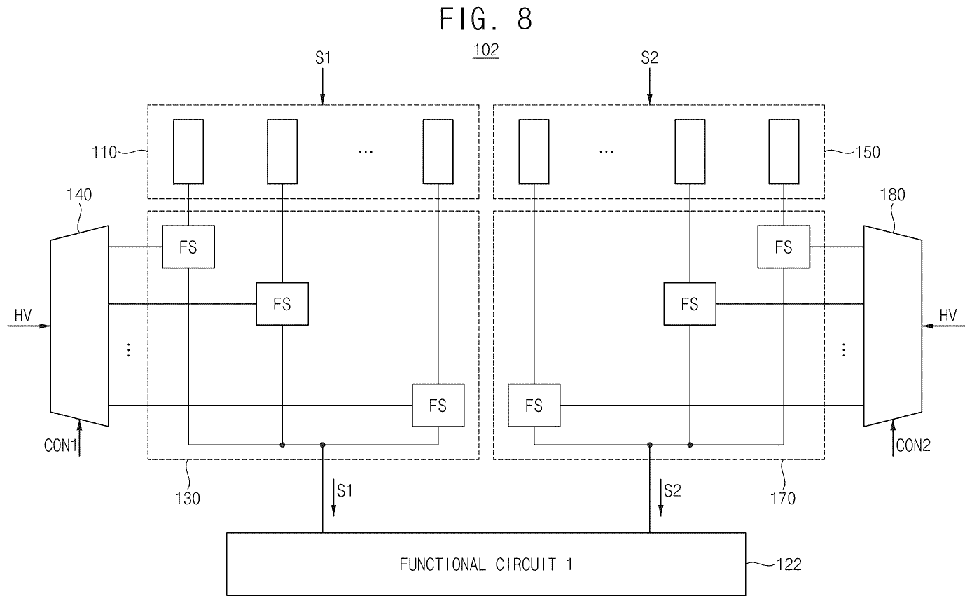

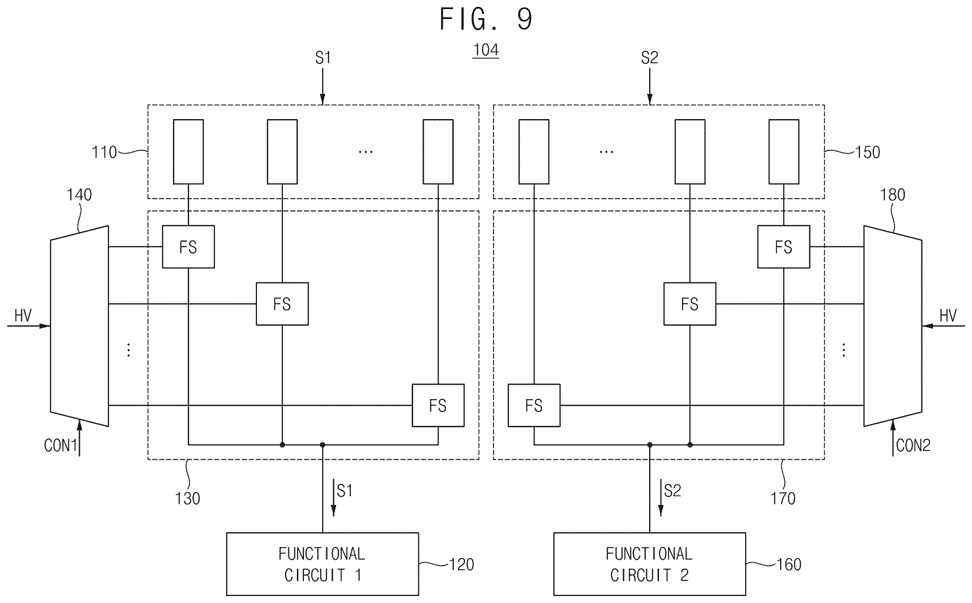

FIGS. 8 and 9 are block diagrams illustrating a semiconductor chip according to example implementations.

Referring to FIG. 8, a semiconductor chip 102 includes a plurality of first pads 110, a first functional circuit 122, a plurality of first fuses 130 and a first demultiplexer 140, and may further include a plurality of second pads 150, a plurality of second fuses (FSs) 170 and a second demultiplexer 180.

The semiconductor chip 102 may be substantially the same as the semiconductor chip 100 of FIG. 1, except that the semiconductor chip 102 further includes the plurality of second pads 150, the plurality of second fuses 170 and the second demultiplexer 180. The descriptions repeated with or overlapping with descriptions of FIG. 1 will be omitted in the interest of brevity.

The plurality of second pads 150 may receive a second signal S2 that is required to operate the semiconductor chip 102. For example, the plurality of second pads 150 may include a first signal pad to an M-th signal pad, where M is a positive integer greater than or equal to two. In some example implementations, the number of the plurality of first pads 110 and the number of the plurality of second pads 150 may be equal to each other (e.g., N=M), or may be different from each other (e.g., N>M or N<M).

The first functional circuit 122 may operate based on the first signal S1 that is received from one of the plurality of first pads 110 and the second signal S2 that is received from one of the plurality of second pads 150.

The plurality of second fuses 170 may be disposed or arranged between the first functional circuit 122 and the plurality of second pads 150. For example, each of the plurality of second fuses 170 may be disposed between the first functional circuit 122 and a respective one of the plurality of second pads 150. In other words, one second fuse may be disposed to correspond to one second pad, and thus the number of the plurality of second fuses 170 may be equal to the number of the plurality of second pads 150. For example, the semiconductor chip 102 may include M second fuses.

The second demultiplexer 180 may apply the high voltage HV to at least one of the plurality of second fuses 170 based on a second control signal CON2. The at least one of the plurality of second fuses 170 to which the high voltage HV is applied may be programmed.

In some example implementations, as with the first control signal CON1, the second control signal CON2 for selecting a fuse to be programmed among the plurality of second fuses 170 may be provided from the outside of the semiconductor chip 102.

For example, one pad of the plurality of second pads 150 may be electrically connected to the first functional circuit 122 through one fuse of the plurality of second fuses 170, and remaining pads of the plurality of second pads 150 other than the one pad of the plurality of second pads 150 may be electrically disconnected or isolated from the first functional circuit 122 by remaining fuses of the plurality of second fuses 170 other than the one fuse of the plurality of second fuses 170. For example, only the one pad of the plurality of second pads 150 that is electrically connected to the first functional circuit 122 may be used as a pad for receiving the second signal S2, and the remaining pads of the plurality of second pads 150 other than the one pad of the plurality of second pads 150 may be provided as dummy pads. In other words, the plurality of second pads 150 that are used to receive the second signal S2 may be set as one pad group, and one pad may be selected and used from the one pad group. In addition, the one pad that is selected and used from the one pad group may be changeable.

The plurality of second pads 150, the plurality of second fuses 170 and the second demultiplexer 180 may be substantially the same as the plurality of first pads 110, the plurality of first fuses 130 and the first demultiplexer 140, respectively. For example, the plurality of second pads 150 and the plurality of second fuses 170 may be implemented as described with reference to FIGS. 2 through 7.

In some example implementations, configurations and operations of the plurality of first fuses 130 may be substantially the same as configurations and operations of the plurality of second fuses 170. For example, when the plurality of first fuses 130 include only anti-fuses as illustrated in FIG. 2, the plurality of second fuses 170 may also include only anti-fuses.

In some example implementations, configurations and operations of the plurality of first fuses 130 may be different from configurations and operations of the plurality of second fuses 170. For example, the plurality of first fuses 130 may include only anti-fuses as illustrated in FIG. 2, and the plurality of second fuses 170 may include only electrical fuses as illustrated in FIG. 4.

Referring to FIG. 9, a semiconductor chip 104 includes a plurality of first pads 110, a first functional circuit 120, a plurality of first fuses 130 and a first demultiplexer 140, and may further include a plurality of second pads 150, a second functional circuit 160, a plurality of second fuses 170 and a second demultiplexer 180.

The semiconductor chip 104 may be substantially the same as the semiconductor chip 100 of FIG. 1, except that the semiconductor chip 104 further includes the plurality of second pads 150, the second functional circuit 160, the plurality of second fuses 170 and the second demultiplexer 180. The plurality of second pads 150, the plurality of second fuses 170 and the second demultiplexer 180 may be substantially the same as those described with reference to FIG. 8. The descriptions repeated with or overlapping with descriptions of FIGS. 1 and 8 will be omitted in the interest of brevity.

The second functional circuit 160 may operate based on the second signal S2 that is received from one of the plurality of second pads 150.

Although example implementations are described based on the examples where the number of pad groups is two and the number of functional circuits is one or two, example implementations are not limited thereto, and the number of pad groups and/or the number of corresponding functional circuits may be variously determined according to example implementations.

FIGS. 10A and 10B are block diagrams illustrating examples of a semiconductor chip according to example implementations.

Referring to FIG. 10A, an example where the semiconductor chip is or includes a memory (or memory chip) is illustrated. For example, a memory 200 may be one of various volatile memories such as a dynamic random access memory (DRAM).

The memory 200 may include a control logic 210, a refresh control circuit 215, an address register 220, a bank control logic 230, a row address multiplexer 240, a column address latch 250, a row decoder, a column decoder, a memory cell array, a sense amplifier unit, an input/output (I/O) gating circuit 290, a data I/O buffer 295 and pads 201, 202 and 203.

The memory cell array may include a plurality of memory cells. The memory cell array may include a plurality of bank arrays, e.g., first to fourth bank arrays 280a, 280b, 280c and 280d. The row decoder may include a plurality of bank row decoders, e.g., first to fourth bank row decoders 260a, 260b, 260c and 260d connected to the first to fourth bank arrays 280a, 280b, 280c and 280d, respectively. The column decoder may include a plurality of bank column decoders, e.g., first to fourth bank column decoders 270a, 270b, 270c and 270d connected to the first to fourth bank arrays 280a, 280b, 280c and 280d, respectively. The sense amplifier unit may include a plurality of bank sense amplifiers, e.g., first to fourth bank sense amplifiers 285a, 285b, 285c and 285d connected to the first to fourth bank arrays 280a, 280b, 280c and 280d, respectively.

The first to fourth bank arrays 280a to 280d, the first to fourth bank row decoders 260a to 260d, the first to fourth bank column decoders 270a to 270d, and the first to fourth bank sense amplifiers 285a to 285d may form first to fourth banks, respectively. For example, the first bank array 280a, the first bank row decoder 260a, the first bank column decoder 270a, and the first bank sense amplifier 285a may form the first bank; the second bank array 280b, the second bank row decoder 260b, the second bank column decoder 270b, and the second bank sense amplifier 285b may form the second bank; the third bank array 280c, the third bank row decoder 260c, the third bank column decoder 270c, and the third bank sense amplifier 285c may form the third bank; and the fourth bank array 280d, the fourth bank row decoder 260d, the fourth bank column decoder 270d, and the fourth bank sense amplifier 285d may form the fourth bank.

The address register 220 may receive an address ADDR including a bank address BANK_ADDR, a row address ROW_ADDR and a column address COL_ADDR from a controller located outside the memory 200. The address register 220 may provide the received bank address BANK_ADDR to the bank control logic 230, may provide the received row address ROW_ADDR to the row address multiplexer 240, and may provide the received column address COL_ADDR to the column address latch 250.

The bank control logic 230 may generate bank control signals in response to receipt of the bank address BANK_ADDR. One of the first to fourth bank row decoders 260a to 260d corresponding to the received bank address BANK_ADDR may be activated in response to the bank control signals generated by the bank control logic 230, and one of the first to fourth bank column decoders 270a to 270d corresponding to the received bank address BANK_ADDR may be activated in response to the bank control signals generated by the bank control logic 230.

The refresh control circuit 215 may generate a refresh address REF_ADDR in response to receipt of a refresh command or entrance of any self-refresh mode. For example, the refresh control circuit 215 may include a refresh counter that is configured to sequentially change the refresh address REF_ADDR from a first address of the memory cell array to a last address of the memory cell array. The refresh control circuit 215 may receive control signals from the control logic 210.

The row address multiplexer 240 may receive the row address ROW_ADDR from the address register 220, and may receive the refresh address REF_ADDR from the refresh control circuit 215. The row address multiplexer 240 may selectively output the row address ROW_ADDR or the refresh address REF_ADDR. A row address (e.g., the row address ROW_ADDR or the refresh address REF_ADDR) output from the row address multiplexer 240 may be applied to the first to fourth bank row decoders 260a to 260d.

The activated one of the first to fourth bank row decoders 260a to 260d may decode the row address output from the row address multiplexer 240, and may activate a wordline corresponding to the row address. For example, the activated bank row decoder may apply a wordline driving voltage to the wordline corresponding to the row address.

The column address latch 250 may receive the column address COL_ADDR from the address register 220, and may temporarily store the received column address COL_ADDR. The column address latch 250 may apply the temporarily stored or received column address COL_ADDR to the first to fourth bank column decoders 270a to 270d.

The activated one of the first to fourth bank column decoders 270a to 270d may decode the column address COL_ADDR output from the column address latch 250, and may control the I/O gating circuit 290 to output data corresponding to the column address COL_ADDR.

The I/O gating circuit 290 may include a circuitry for gating I/O data. For example, although not shown, the I/O gating circuit 290 may include an input data mask logic, read data latches for storing data output from the first to fourth bank arrays 280a to 280d, and write drivers for writing data to the first to fourth bank arrays 280a to 280d.

Data DQ to be read from one of the first to fourth bank arrays 280a to 280d may be sensed by a sense amplifier coupled to the one bank array, and may be stored in the read data latches. The data DQ stored in the read data latches may be provided to the controller via the data I/O buffer 295. Data DQ that are to be written to one of the first to fourth bank arrays 280a to 280d may be provided from the controller to the data I/O buffer 295. The data DQ provided to the data I/O buffer 295 may be written to the one bank array via the write drivers in the I/O gating circuit 290.

The control logic 210 may control an operation of the memory 200. For example, the control logic 210 may generate control signals for the memory 200 to perform a data write operation or a data read operation. The control logic 210 may include a command decoder 211 that decodes a command CMD received from the controller and a mode register 212 that sets an operation mode of the memory 200.

The memory 200 may receive the command CMD through the pad 201, may receive the address ADDR through the pad 202, and may receive or output the data DQ through the pad 203. Each of the pads 201, 202 and 203 may be implemented based on the examples described with reference to FIGS. 1 through 9. For example, each of the pads 201, 202 and 203 may have a structure in which a plurality of pads form one pad group, a structure including fuses and a demultiplexer that are connected to one pad group, and a structure of the pad coordinate variable scheme in which the role and function of pads are changeable. In some example implementations, the command CMD and the address ADDR may be provided as a single command/address (CA) signal.

Referring to FIG. 10B, an example where the semiconductor chip is or includes a memory (or memory chip) is illustrated. For example, a memory 300 may be one of various nonvolatile memories such as a NAND flash memory.

The memory 300 may include a memory cell array 310, an address decoder 320, a page buffer circuit 330, a data input/output (I/O) circuit 340, a voltage generator 350, a control circuit 360 and pads 301, 302 and 303.

The memory cell array 310 may be connected to the address decoder 320 via a plurality of string selection lines SSL, a plurality of wordlines WL and a plurality of ground selection lines GSL. The memory cell array 310 may be further connected to the page buffer circuit 330 via a plurality of bitlines BL. The memory cell array 310 may include a plurality of memory cells (e.g., a plurality of nonvolatile memory cells) that are connected to the plurality of wordlines WL and the plurality of bitlines BL. The memory cell array 310 may be divided into a plurality of memory blocks BLK1, BLK2, . . . , BLKz each of which includes memory cells.

In some example implementations, the plurality of memory cells may be arranged in a two-dimensional (2D) array structure or a three-dimensional (3D) vertical array structure. A three-dimensional vertical array structure may include vertical cell strings that are vertically oriented such that at least one memory cell is located over another memory cell. The at least one memory cell may comprise a charge trap layer. The following patent documents, which are hereby incorporated by reference in their entirety, describe suitable configurations for a memory cell array including a 3D vertical array structure, in which the three-dimensional memory array is configured as a plurality of levels, with wordlines and/or bitlines shared between levels: U.S. Pat. Nos. 7,679,133; 8,553,466; 8,654,587; 8,559,235; and US Pat. Pub. No. 2011/0233648.

The control circuit 360 may receive a command CMD and an address ADDR from a controller located outside the memory 300, and may control erasure, programming and read operations of the memory 300 based on the command CMD and the address ADDR. An erasure operation may include performing a sequence of erase loops, and a programming operation may include performing a sequence of program loops. Each program loop may include a program operation and a program verification operation. Each erase loop may include an erase operation and an erase verification operation. The read operation may include a normal read operation and data recovery read operation.

For example, the control circuit 360 may generate control signals CON, which are used for controlling the voltage generator 350, and may generate control signal PBC for controlling the page buffer circuit 330, based on the command CMD, and may generate a row address R_ADDR and a column address C_ADDR based on the address ADDR. The control circuit 360 may provide the row address R_ADDR to the address decoder 320 and may provide the column address C_ADDR to the data I/O circuit 340.

The address decoder 320 may be connected to the memory cell array 310 via the plurality of string selection lines SSL, the plurality of wordlines WL and the plurality of ground selection lines GSL. For example, in the data erase/write/read operations, the address decoder 320 may determine at least one of the plurality of wordlines WL as a selected wordline, at least one of the plurality of string selection lines SSL as a selected string selection line, and at least one of the plurality of ground selection lines GSL as a selected ground selection line, based on the row address R_ADDR.

The voltage generator 350 may generate voltages VS that are required for an operation of the memory 300 based on a power PWR and the control signals CON. The voltages VS may be applied to the plurality of string selection lines SSL, the plurality of wordlines WL and the plurality of ground selection lines GSL via the address decoder 320. In addition, the voltage generator 350 may generate an erase voltage VERS that is required for the erase operation based on the power PWR and the control signals CON.

The page buffer circuit 330 may be connected to the memory cell array 310 via the plurality of bitlines BL. The page buffer circuit 330 may include a plurality of page buffers. The page buffer circuit 330 may store data DAT to be programmed into the memory cell array 310 or may read data DAT sensed from the memory cell array 310. In other words, the page buffer circuit 330 may operate as a write driver or a sensing amplifier according to an operation mode of the memory 300.

The data I/O circuit 340 may be connected to the page buffer circuit 330 via data lines DL. The data I/O circuit 340 may provide the data DAT from the outside of the memory 300 to the memory cell array 310 via the page buffer circuit 330 or may provide the data DAT from the memory cell array 310 to the outside of the memory 300, based on the column address C_ADDR.

The memory 300 may receive the command CMD through the pad 301, may receive the address ADDR through the pad 302, and may receive or output the data DAT through the pad 303. Each of the pads 301, 302 and 303 may be implemented based on the examples described with reference to FIGS. 1 through 9. For example, each of the pads 301, 302 and 303 may have a structure in which a plurality of pads form one pad group, a structure including fuses and a demultiplexer that are connected to one pad group, and a structure of the pad coordinate variable scheme in which the role and function of pads are changeable. In some example implementations, the command CMD and the address ADDR may be provided as a single command/address (CA) signal.

Although the semiconductor chip according to example implementations is described based on a DRAM and a NAND flash memory, the semiconductor chip according to example implementations may be or include any volatile memory, and/or any nonvolatile memory, e.g., a static random access memory (SRAM), a phase-change random access memory (PRAM), a resistive random access memory (RRAM), a magnetic random access memory (MRAM), a ferroelectric random access memory (FRAM), etc.

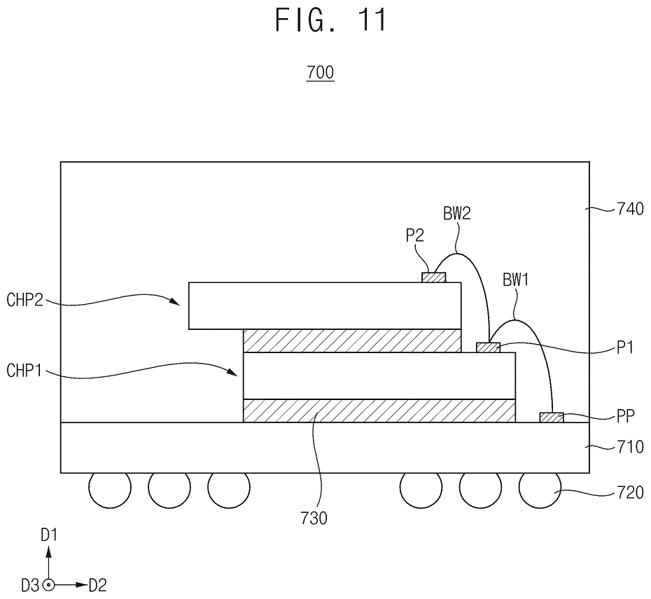

FIG. 11 is a cross-sectional view of a semiconductor package according to example implementations.

Hereinafter, in the specification (and not necessarily in the claims), a vertical direction that is substantially perpendicular to an upper surface of a substrate (e.g., a semiconductor substrate and/or a package substrate) may be referred to as a first direction D1, and two intersecting directions among horizontal directions that are substantially parallel to the upper surface of the substrate may be referred to as second and third directions D2 and D3, respectively. For example, the second and third directions D2 and D3 may be substantially perpendicular to each other. Each of the first, second and third directions D1, D2 and D3 may include not only a direction shown in the drawings but also a direction inverse thereto.

Referring to FIG. 11, a semiconductor package 700 includes a package substrate (or base substrate) 710, a first semiconductor chip CHP1 that is disposed on the package substrate 710, and a second semiconductor chip CHP2 that is disposed on the first semiconductor chip CHP1.

The package substrate 710 includes a plurality of substrate pads PP. For example, the package substrate 710 may be a substrate having an upper surface and a lower surface opposite to each other. For example, the package substrate 710 may be a printed circuit board (PCB). The PCB may include wirings and vias connected to the wirings. The wirings may include printed circuit patterns for interconnection with the electronic elements.

The first semiconductor chip CHP1 includes a plurality of first pads P1, and the second semiconductor chip CHP2 includes a plurality of second pads P2. Each of the first and second semiconductor chips CHP1 and CHP2 may be the semiconductor chip according to example implementations.

In some example implementations, the semiconductor chips CHP1 and CHP2 may be stacked on the package substrate 710 such that a surface on which the pads P1 and P2 are formed faces upwards. In some example implementations, with respect to each of the semiconductor chips CHP1 and CHP2, the pads P1 and P2 may be arranged near one side of the semiconductor substrate. As such, the semiconductor chips CHP1 and CHP2 may be stacked scalariformly, that is, in a step shape, such that the pads P1 and P2 of each semiconductor chip may be exposed. In such stacked state, the semiconductor chips CHP1 and CHP2 may be electrically connected to the package substrate 710 through bonding wires BW1 and BW2.

The stacked semiconductor chips CHP1 and CHP2 and the bonding wires BW1 and BW2 may be fixed by a sealing member 740, and adhesive members 730 may intervene between the package substrate 710 and the semiconductor chips CHP1 and CHP2. Conductive bumps 720 may be formed on a bottom surface of the package substrate 710 for electrical connections to an external device.

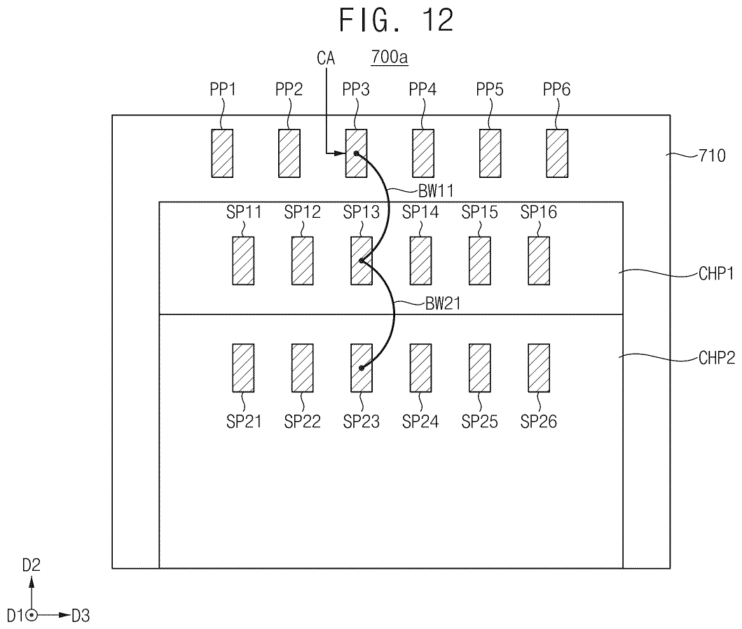

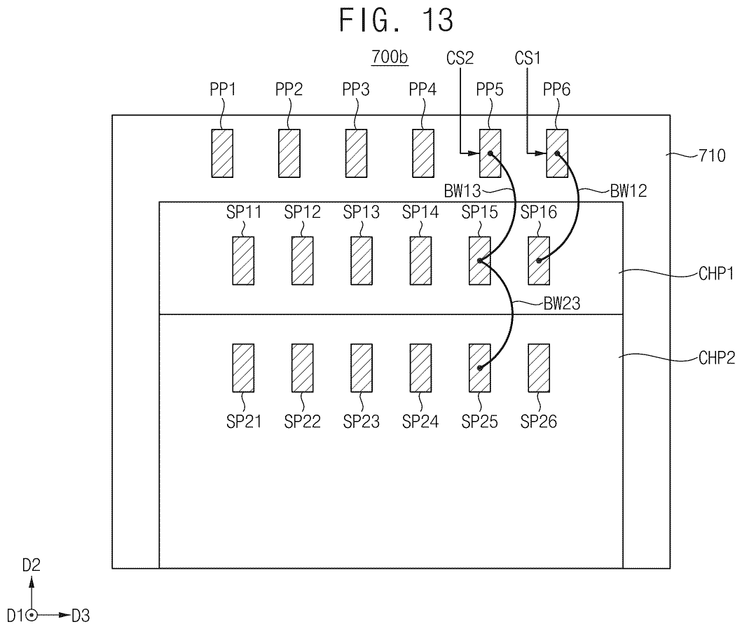

FIGS. 12 and 13 are plan views of examples of a semiconductor package of FIG. 11.

Referring to FIG. 12, a semiconductor package 700a may include a package substrate 710, a first semiconductor chip CHP1 and a second semiconductor chip CHP2 that are electrically connected by bonding wires BW11 and BW21.

A plurality of substrate pads PP that are included in the package substrate 710 may include first, second, third, fourth, fifth and sixth substrate pads PP1, PP2, PP3, PP4, PP5 and PP6.

A plurality of first pads P1 that are included in the first semiconductor chip CHP1 may include first, second, third, fourth, fifth and sixth signal pads SP11, SP12, SP13, SP14, SP15 and SP16. Although not illustrated in detail, as described with reference to FIGS. 1 through 9, the first semiconductor chip CHP1 may further include at least one first functional circuit, first, second, third, fourth, fifth and sixth fuses disposed between the first functional circuit and the first, second, third, fourth, fifth and sixth signal pads SP11, SP12, SP13, SP14, SP15 and SP16, and at least one first demultiplexer.

The first semiconductor chip CHP1 may operate based on a signal CA that is received from the third substrate pad PP3 through the third signal pad SP13. For example, as illustrated in FIG. 12, the third substrate pad PP3 and the third signal pad SP13 may be electrically connected to each other through the bonding wire BW11. In addition, as described with reference to FIGS. 2 through 7, only the third fuse connected to the third signal pad SP13 may be programmed, or the first, second, fourth, fifth and sixth fuses other than the third fuse may be programmed, so that the third signal pad SP13 and the first functional circuit included in the first semiconductor chip CHP1 may be electrically connected to each other, and thus the signal CA received from the third substrate pad PP3 through the third signal pad SP13 may be provided to the first functional circuit.

A plurality of second pads P2 that are included in the second semiconductor chip CHP2 may include seventh, eighth, ninth, tenth, eleventh and twelfth signal pads SP21, SP22, SP23, SP24, SP25 and SP26. Although not illustrated in detail, the second semiconductor chip CHP2 may further include at least one second functional circuit, seventh, eighth, ninth, tenth, eleventh and twelfth fuses disposed between the second functional circuit and the seventh, eighth, ninth, tenth, eleventh and twelfth signal pads SP21, SP22, SP23, SP24, SP25 and SP26, and at least one second demultiplexer.

The second semiconductor chip CHP2 may operate based on the signal CA that is received from the third substrate pad PP3 through the third signal pad SP13 and the ninth signal pad SP23. For example, as illustrated in FIG. 12, the third substrate pad PP3 and the third signal pad SP13 may be electrically connected to each other through the bonding wire BW11, and the third signal pad SP13 and the ninth signal pad SP23 may be electrically connected to each other through the bonding wire BW21. In addition, as described with reference to FIGS. 2 through 7, only the ninth fuse connected to the ninth signal pad SP23 may be programmed, or the seventh, eighth, tenth, eleventh and twelfth fuses other than the ninth fuse may be programmed, so that the ninth signal pad SP23 and the second functional circuit included in the second semiconductor chip CHP2 may be electrically connected to each other, and thus the signal CA received from the third substrate pad PP3 through the third signal pad SP13 and the ninth signal pad SP23 may be provided to the second functional circuit.

In some example implementations, a first position in the first semiconductor chip CHP1 and a second position in the second semiconductor chip CHP2 may be in the same position. In the first semiconductor chip CHP1, the first position may represent a position of the third signal pad SP13 that is electrically connected to the first functional circuit. In the second semiconductor chip CHP2, the second position may represent a position of the ninth signal pad SP23 that is electrically connected to the second functional circuit. For example, when the first and second semiconductor chips CHP1 and CHP2 are overlapped and viewed on the same plane, the first position of the third signal pad SP13 and the second position of the ninth signal pad SP23 may completely overlap and match each other.

In some example implementations, the first and second semiconductor chips CHP1 and CHP2 may be memory chips of the same type, and the semiconductor package 700a may be a memory package including the memory chips.

In some example implementations, the signal CA may be a command/address signal. When the semiconductor package 700a is a memory package, memory chips included in one memory package may operate based on the same command/address signal, and the positions of the signal pads SP13 and SP23 that receive the same command/address signal may be in the same position.

Referring to FIG. 13, a semiconductor package 700b may include a package substrate 710, a first semiconductor chip CHP1 and a second semiconductor chip CHP2 that are electrically connected by bonding wires BW12, BW13 and BW23. The descriptions repeated with or overlapping with descriptions of FIG. 12 will be omitted in the interest of brevity.

The first semiconductor chip CHP1 may operate based on a signal CS1 that is received from the sixth substrate pad PP6 through the sixth signal pad SP16. For example, as illustrated in FIG. 13, the sixth substrate pad PP6 and the sixth signal pad SP16 may be electrically connected to each other through the bonding wire BW12. In addition, as described with reference to FIGS. 2 through 7, only the sixth fuse connected to the sixth signal pad SP16 may be programmed, or the first, second, third, fourth and fifth fuses other than the sixth fuse may be programmed, so that the sixth signal pad SP16 and the first functional circuit included in the first semiconductor chip CHP1 may be electrically connected to each other, and thus the signal CS1 received from the sixth substrate pad PP6 through the sixth signal pad SP16 may be provided to the first functional circuit.

The second semiconductor chip CHP2 may operate based on a signal CS2 that is received from the fifth substrate pad PP5 through the fifth signal pad SP15 and the eleventh signal pad SP25. For example, as illustrated in FIG. 13, the fifth substrate pad PP5 and the fifth signal pad SP15 may be electrically connected to each other through the bonding wire BW13, and the fifth signal pad SP15 and the eleventh signal pad SP25 may be electrically connected to each other through the bonding wire BW23. In addition, as described with reference to FIGS. 2 through 7, only the eleventh fuse connected to the eleventh signal pad SP25 may be programmed, or the seventh, eighth, ninth, tenth and twelfth fuses other than the eleventh fuse may be programmed, so that the eleventh signal pad SP25 and the second functional circuit included in the second semiconductor chip CHP2 may be electrically connected to each other, and thus the signal CS2 received from the fifth substrate pad PP5 through the fifth signal pad SP15 and the eleventh signal pad SP25 may be provided to the second functional circuit.

In some example implementations, a third position in the first semiconductor chip CHP1 and a fourth position in the second semiconductor chip CHP2 may be in different positions. In the first semiconductor chip CHP1, the third position may represent a position of the sixth signal pad SP16 that is electrically connected to the first functional circuit. In the second semiconductor chip CHP2, the fourth position may represent a position of the eleventh signal pad SP25 that is electrically connected to the second functional circuit.

In some example implementations, the signal CS1 may be a first chip selection signal for selecting the first semiconductor chip CHP1, and the signal CS2 may be a second chip selection signal for selecting the second semiconductor chip CHP2. When the semiconductor package 700b is a memory package, memory chips included in one memory package may operate based on different chip selection signals, and the positions of the signal pads SP16 and SP25 that receive the different chip selection signals may be in different positions.

In a conventional semiconductor package, positions of pads that receive signals of the same type were always in the same position in semiconductor chips of the same type. However, in the semiconductor package according to example implementations implemented with the pad coordinate variable scheme in which the role and function of pads are changeable, the positions of the signal pads SP16 and SP25 that receive the chip selection signals CS1 and CS2 of the same type may be in different positions in the first and second semiconductor chips CHP1 and CHP2 of the same type. Accordingly, a relatively free arrangement of bonding wires may be implemented, defects of bonding wires such as open and short may be efficiently controlled, and the usage amount of bonding wire may be reduced.

In some example implementations, the semiconductor package according to example implementations may be implemented by combining the examples of FIGS. 12 and 13. For example, when the semiconductor chips CHP1 and CHP2 are stacked on the package substrate 710 and operate based on the same signal CA and different signals CS1 and CS2, the positions of the signal pads SP13 and SP23 that receive the signals CA may be in the same position in the semiconductor chips CHP1 and CHP2 as illustrated in FIG. 12, and the positions of the signal pads SP16 and SP25 that receive the signals CS1 and CS2 may be in different positions in the semiconductor chips CHP1 and CHP2 as illustrated in FIG. 13.

Although example implementations are described based on the examples where the number of stacked semiconductor chips is two, the number of substrate pads and the number of signal pads are six, and the specific signals CA, CS1 and CS2 are received, example implementations are not limited thereto, and the number of semiconductor chips, the number of pads, the type and number of signals, and the connection scheme of the pads according to the same may be variously determined according to example implementations.

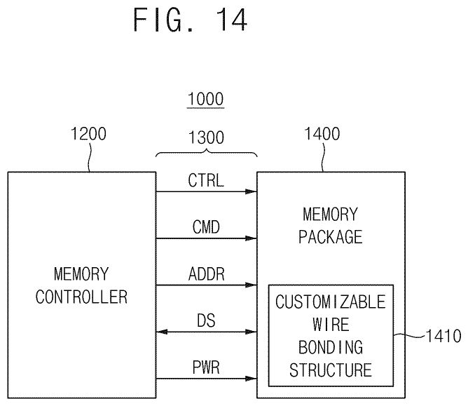

FIG. 14 is a block diagram illustrating a memory system according to example implementations.

Referring to FIG. 14, a memory system 1000 includes a memory controller 1200 and a memory package 1400. The memory system 1000 may further include a plurality of signal lines 1300 that electrically connect the memory controller 1200 with the memory package 1400.

The memory package 1400 is controlled by the memory controller 1200. For example, based on requests from a host (not illustrated), the memory controller 1200 may store (e.g., write or program) data into the memory package 1400, or may retrieve (e.g., read or sense) data from the memory package 1400.

The memory package 1400 may be implemented based on the examples described with reference to FIGS. 11 through 13, and each of memory chips included in the memory package 1400 may be implemented based on the examples described with reference to FIGS. 1 through 9. The memory package 1400 may have a customizable wire bonding structure 1410 according example implementations. The customizable wire bonding structure 1410 may represents the structure in which the plurality of pads form the one pad group, the structure including the fuses and the demultiplexer that are connected to the one pad group, and the structure of the pad coordinate variable scheme in which the role and function of pads are changeable, which are described with reference to FIGS. 1 through 9, and may represent the structure for implementing a relatively free arrangement of bonding wires, which is described with reference to FIGS. 11 through 13.

The plurality of signal lines 1300 may include control lines, command lines, address lines, data input/output (I/O) lines and power lines. The memory controller 1200 may transmit a command CMD, an address ADDR and a control signal CTRL to the memory package 1400 via the command lines, the address lines and the control lines, may exchange a data signal DS with the memory package 1400 via the data I/O lines, and may transmit a power supply voltage PWR to the memory package 1400 via the power lines. Although not illustrated in detail, the plurality of signal lines 1300 may further include data strobe signal (DQS) lines for transmitting a DQS signal.

The example implementations may be applied to various electronic devices and systems that include the semiconductor chips and the semiconductor packages. For example, the example implementations may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automotive, etc.

The foregoing is illustrative of example implementations and is not to be construed as limiting thereof. Although some example implementations have been described, those skilled in the art will readily appreciate that many modifications are possible in the example implementations without materially departing from the novel teachings and advantages of the example implementations. Accordingly, all such modifications are intended to be included within the scope of the example implementations as defined in the claims. Therefore, it is to be understood that the foregoing is illustrative of various example implementations and is not to be construed as limited to the specific example implementations disclosed, and that modifications to the disclosed example implementations, as well as other example implementations, are intended to be included within the scope of the appended claims.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor chip comprising:
a plurality of first pads;
a first functional circuit configured to operate based on a first signal from a first pad of the plurality of first pads;
a plurality of first fuses between the first functional circuit and the plurality of first pads; and
a first demultiplexer configured to apply a first voltage to at least one of the plurality of first fuses based on a first control signal,
wherein the first pad of the plurality of first pads is configured to be electrically connected to the first functional circuit through a first fuse of the plurality of first fuses, and
wherein remaining first pads of the plurality of first pads other than the first pad of the plurality of first pads are configured to be electrically disconnected from the first functional circuit by remaining first fuses of the plurality of first fuses other than the first fuse of the plurality of first fuses.

2. The semiconductor chip of claim 1,
wherein the plurality of first pads include a first signal pad to an N-th signal pad, and N is a positive integer greater than or equal to two, and
wherein the plurality of first fuses include a first anti-fuse to an N-th anti-fuse that are between the first functional circuit and the first signal pad to the N-th signal pad, respectively.

3. The semiconductor chip of claim 2, wherein the semiconductor chip is configured to, based on the first signal pad being the first pad of the plurality of first pads, deselect the first signal pad and select a second signal pad of the plurality of first pads for receiving the first signal.

4. The semiconductor chip of claim 2, wherein the semiconductor chip is configured to receive the first signal through the first signal pad and to provide the first signal to the first functional circuit.

5. The semiconductor chip of claim 4,
wherein the first anti-fuse that is between the first functional circuit and the first signal pad is configured to be programmed by applying the first voltage, and
wherein a second anti-fuse to the N-th anti-fuse that are respectively between the first functional circuit and a second signal pad to the N-th signal pad are configured to be blocked from applying the first voltage.

6. The semiconductor chip of claim 1,
wherein the plurality of first pads include a first signal pad to an N-th signal pad, and N is a positive integer greater than or equal to two, and
wherein the plurality of first fuses include a first electrical fuse to an N-th electrical fuse that are between the first functional circuit and the first signal pad to the N-th signal pad, respectively.

7. The semiconductor chip of claim 6, wherein the semiconductor chip is configured to receive the first signal through the first signal pad and to provide the first signal to the first functional circuit.

8. The semiconductor chip of claim 7,
wherein the first electrical fuse that is between the first functional circuit and the first signal pad is configured to be blocked from applying the first voltage, and
wherein a second electrical fuse to the N-th electrical fuse that are respectively between the first functional circuit and a second signal pad to the N-th signal pad are configured to be programmed by applying the first voltage.

9. The semiconductor chip of claim 1,
wherein the plurality of first pads include a first signal pad to an N-th signal pad, and N is a positive integer greater than or equal to two, and
wherein the plurality of first fuses include:
an electrical fuse that is between the first functional circuit and the first signal pad, and
a first anti-fuse to an (N-1)-th anti-fuse that are respectively between (i) the first functional circuit and (ii) a second signal pad to the N-th signal pad other than the first signal pad.

10. The semiconductor chip of claim 9,
wherein the semiconductor chip is configured to, before a first time point, receive the first signal through the first signal pad and provide the first signal to the first functional circuit through the first signal pad, and
wherein the semiconductor chip is configured to, after the first time point, receive the first signal through the second signal pad and provide the first signal to the first functional circuit through the second signal pad.

11. The semiconductor chip of claim 10,
wherein the semiconductor chip is configured to, at the first time point, program the first anti-fuse and the electrical fuse by applying the first voltage, and the first anti-fuse is between the first functional circuit and the second signal pad, and
wherein the semiconductor chip is configured to block a second anti-fuse to the (N-1)-th anti-fuse from applying the first voltage, and the second anti-fuse and the (N-1)-th anti-fuse are respectively between the first functional circuit and a third signal pad to the N-th signal pad.

12. The semiconductor chip of claim 1, comprising:
a plurality of second pads;
a plurality of second fuses between the first functional circuit and the plurality of second pads; and
a second demultiplexer configured to apply the first voltage to at least one of the plurality of second fuses based on a second control signal,
wherein the first functional circuit is configured to operate based on a second signal from a second pad of the plurality of second pads,
wherein the second pad of the plurality of second pads is configured to be electrically connected to the first functional circuit through a second fuse of the plurality of second fuses, and
wherein remaining second pads of the plurality of second pads other than the second pad of the plurality of second pads are configured to be electrically disconnected from the first functional circuit by remaining second fuses of the plurality of second fuses other than the second fuse of the plurality of second fuses.

13. The semiconductor chip of claim 1, comprising:
a plurality of second pads;
a second functional circuit configured to operate based on a second signal from a second pad of the plurality of second pads;
a plurality of second fuses between the second functional circuit and the plurality of second pads; and
a second demultiplexer configured to apply the first voltage to at least one of the plurality of second fuses based on a second control signal,
wherein the second pad of the plurality of second pads is configured to be electrically connected to the second functional circuit through a second fuse of the plurality of second fuses, and
wherein remaining second pads of the plurality of second pads other than the second pad of the plurality of second pads are configured to be electrically disconnected from the second functional circuit by remaining second fuses of the plurality of second fuses other than the second fuse of the plurality of second fuses.

14. A semiconductor package comprising:
a package substrate including a plurality of substrate pads;
a first semiconductor chip on the package substrate; and
a second semiconductor chip on the first semiconductor chip,
wherein the first semiconductor chip includes:
a plurality of first pads;
a first functional circuit configured to operate based on a first signal that is received from a first substrate pad of the plurality of substrate pads through a first pad of the plurality of first pads;
a plurality of first fuses between the first functional circuit and the plurality of first pads; and
a first demultiplexer configured to apply a first voltage to at least one of the plurality of first fuses based on a first control signal,
wherein the first pad of the plurality of first pads is configured to be electrically connected to the first functional circuit through a first fuse of the plurality of first fuses, and
wherein remaining first pads of the plurality of first pads other than the first pad of the plurality of first pads are configured to be electrically disconnected from the first functional circuit by remaining first fuses of the plurality of first fuses other than the first fuse of the plurality of first fuses.

15. The semiconductor package of claim 14, wherein the second semiconductor chip includes:
a plurality of second pads;
a second functional circuit configured to operate based on the first signal that is received from the first substrate pad through a second pad of the plurality of second pads;
a plurality of second fuses between the second functional circuit and the plurality of second pads; and
a second demultiplexer configured to apply the first voltage to at least one of the plurality of second fuses based on a second control signal,
wherein the second pad of the plurality of second pads is configured to be electrically connected to the second functional circuit through a second fuse of the plurality of second fuses, and
wherein remaining second pads of the plurality of second pads other than the second pad of the plurality of second pads are configured to be electrically disconnected from the second functional circuit by remaining second fuses of the plurality of second fuses other than the second fuse of the plurality of second fuses.

16. The semiconductor package of claim 15,
wherein a first position in the first semiconductor chip and a second position in the second semiconductor chip are overlapped,
wherein the first position is a position of the first pad of the plurality of first pads that is configured to be electrically connected to the first functional circuit, and
wherein the second position is a position of the second pad of the plurality of second pads that is configured to be electrically connected to the second functional circuit.

17. The semiconductor package of claim 14, wherein the second semiconductor chip includes:
a plurality of second pads;
a second functional circuit configured to operate based on a second signal that is received from a second substrate pad of the plurality of substrate pads through a second pad of the plurality of second pads, the second substrate pad being different from the first substrate pad;
a plurality of second fuses between the second functional circuit and the plurality of second pads; and
a second demultiplexer configured to apply the first voltage to at least one of the plurality of second fuses based on a second control signal,
wherein the second pad of the plurality of second pads is configured to be electrically connected to the second functional circuit through a second fuse of the plurality of second fuses, and
wherein remaining second pads of the plurality of second pads other than the second pad of the plurality of second pads are configured to be electrically disconnected from the second functional circuit by remaining second fuses of the plurality of second fuses other than the second fuse of the plurality of second fuses.

18. The semiconductor package of claim 17,
wherein a first position in the first semiconductor chip and a second position in the second semiconductor chip are in different positions,
wherein the first position is a position of the first pad of the plurality of first pads that is configured to be electrically connected to the first functional circuit, and
wherein the second position is a position of the second pad of the plurality of second pads that is configured to be electrically connected to the second functional circuit.

19. The semiconductor package of claim 14, wherein the first semiconductor chip and the second semiconductor chip are memory chips of a same type.

20. A semiconductor package comprising:
a package substrate including a plurality of substrate pads;
a first semiconductor chip on the package substrate, the first semiconductor chip including:
a plurality of first pads;
a first functional circuit;
a plurality of first fuses between the first functional circuit and the plurality of first pads; and
a first demultiplexer configured to apply a first voltage to at least one of the plurality of first fuses based on a first control signal; and
a second semiconductor chip on the first semiconductor chip, the second semiconductor chip including:
a plurality of second pads;
a second functional circuit;
a plurality of second fuses between the second functional circuit and the plurality of second pads; and
a second demultiplexer configured to apply the first voltage to at least one of the plurality of second fuses based on a second control signal,
wherein the first functional circuit is configured to operate (i) based on a first signal that is received from a first substrate pad of the plurality of substrate pads through a first one of the plurality of first pads, and (ii) based on a second signal that is received from a second substrate pad of the plurality of substrate pads through a second one of the plurality of first pads,
wherein the first one of the plurality of first pads and the second one of the plurality of first pads are configured to be electrically connected to the first functional circuit respectively through two of the plurality of first fuses,
wherein the second functional circuit is configured to operate (i) based on the first signal that is received from the first substrate pad through a first one of the plurality of second pads, and (ii) based on a third signal that is received from a third substrate pad of the plurality of substrate pads through a second one of the plurality of second pads,
wherein the first one of the plurality of second pads and the second one of the plurality of second pads are configured to be electrically connected to the second functional circuit respectively through two of the plurality of second fuses,
wherein a first position in the first semiconductor chip and a second position in the second semiconductor chip are overlapped,
wherein the first position is a position of the first one of the plurality of first pads,
wherein the second position is a position of the first one of the plurality of second pads,
wherein a third position in the first semiconductor chip and a fourth position in the second semiconductor chip are in different positions,
wherein the third position is a position of the second one of the plurality of first pads, and
wherein the fourth position is a position of the second one of the plurality of second pads.
